(19) United States
(12) Patent Application Publication
(10) Pub. No.: US 2026/0040592 A1
(43) Pub. Date: Feb. 5, 2026

(54) SEMICONDUCTOR PACKAGE INCLUDING PASSIVE COMPONENTS

(71) Applicant: SK hynix Inc., Icheon-si Gyeonggi-do (KR)

(72) Inventors: Ran KIM, Icheon-si Gyeonggi-do (KR); Sang Hoon YOON, Icheon-si Gyeonggi-do (KR); Ki Yong LEE, Icheon-si Gyeonggi-do (KR)

(73) Assignee: SK hynix Inc., Icheon-si Gyeonggi-do (KR)

(21) Appl. No.: 19/001,745

(22) Filed: Dec. 26, 2024

(30) Foreign Application Priority Data
Jul. 31, 2024 (KR) 10-2024-0101369

(51) Int. Cl. H10D 1/68; H01L 25/18

(52) U.S. Cl. CPC H10D 1/68; H01L 25/18

(57) ABSTRACT

A semiconductor package includes a semiconductor chip disposed on a substrate; a first passive component and a second passive component disposed on the substrate; and an encapsulant disposed on the substrate and covering the semiconductor chip, the first passive component, and the second passive component. A first electrode is disposed on an insulating layer of the substrate between the first passive component and the insulating layer. A second electrode is disposed on the insulating layer between the second passive component and the insulating layer and spaced apart from the first electrode. A first dam structure is disposed on the insulating layer. The first dam structure includes a support pattern and a solder resist layer surrounding the support pattern. The first dam structure is disposed between the first electrode and the second electrode.

### CROSS-REFERENCE TO RELATED APPLICATION

The present application claims priority under 35 U.S.C. § 119(a) to Korean Patent Application No. 10-2024-0101369 filed in the Korean Intellectual Property Office on Jul. 31, 2024, which application is incorporated herein by reference in its entirety.

### BACKGROUND

### 1. Technical Field

The present disclosure generally relates to a semiconductor package including passive components.

### 2. Related Art

A semiconductor chip and passive components are mounted on a substrate to provide multifunctionality within a semiconductor package.

Passive components can play a role in suppressing signal interference by functioning as filters. There are several types of passive components, including resistors, capacitors, and inductors. Resistors attenuate signals to reduce reflections. Capacitors and inductors block or eliminate high-frequency noise. Combined in configurations like RC, LC or RLC filter, they effectively mitigate electromagnetic interference (EMI) and enhance circuit stability.

### SUMMARY

In an embodiment, a semiconductor package may include: a semiconductor chip disposed on a substrate; a first passive component and a second passive component disposed on the substrate; and an encapsulant disposed on the substrate and covering the semiconductor chip, the first passive component, and the second passive component. The substrate may include: an insulating layer, a first electrode disposed on the insulating layer between the first passive component and the insulating layer in a third direction; a second electrode disposed on the insulating layer between the second passive component and the insulating layer in the third direction and spaced apart from the first electrode in a first direction perpendicular to the third direction; and a plurality of dam structures disposed on the insulating layer. A first dam structure may include a support pattern and a solder resist layer surrounding the support pattern. The first dam structure may be disposed between the first electrode and the second electrode.

In an embodiment, a semiconductor package may include a first electrode disposed on an insulating layer. A first passive component may be disposed on the first electrode. A second electrode may be disposed on the insulating layer and spaced apart from the first electrode in a first direction. A second passive component may be disposed on the second electrode. A first support pattern may be disposed between the first electrode and the second electrode and disposed on the insulating layer. A solder resist layer may surround the support pattern.

In an embodiment, a semiconductor package may include a first electrode and a second electrode on an insulating layer spaced apart each other in a first direction; a first passive component disposed on the first electrode; a second passive component disposed on the second electrode; a support pattern disposed on the insulating layer between the first electrode and the second electrode; a solder resist layer surrounding the support pattern; a first solder interconnection formed between the first electrode and the first passive component and formed between the first electrode and the solder resist layer in the first direction; and a second solder interconnection formed between the second electrode and the second passive component and formed between the second electrode and the solder resist layer in the first direction.

### BRIEF DESCRIPTION OF THE DRAWINGS

FIG. 1 is a plan view of a semiconductor package according to an embodiment of the present disclosure.

FIG. 2 is a cross-sectional view of a semiconductor package according to an embodiment of the present disclosure.

FIG. 3 and FIG. 4 are cross-sectional views of a semiconductor package according to an embodiment of the present disclosure.

FIG. 5 is a plan view of a semiconductor package according to an embodiment of the present disclosure.

FIG. 6 and FIG. 7 are partial views of a semiconductor package according to an embodiment of the present disclosure.

FIG. 8 is a cross-sectional view of a semiconductor package according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” to another element, the elements may be connected directly or through an intervening element between the elements. When two elements are identified as “directly connected,” one element is directly connected to the other element without an intervening element between the two elements.

When one element is identified as “on” or “over” another element, the elements may directly contact each other or an intervening element may be disposed between the elements.

Terms such as “horizontal,” “over,” “on,” “side,” “upper,” “uppermost,” “lower,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Passive components may be electrically connected to the semiconductor chip through a substrate. When a plurality of passive components are utilized in a semiconductor package, the passive components may be successively or consecutively disposed. The present disclosure describes a semiconductor package including a semiconductor chip and successively disposed passive components.

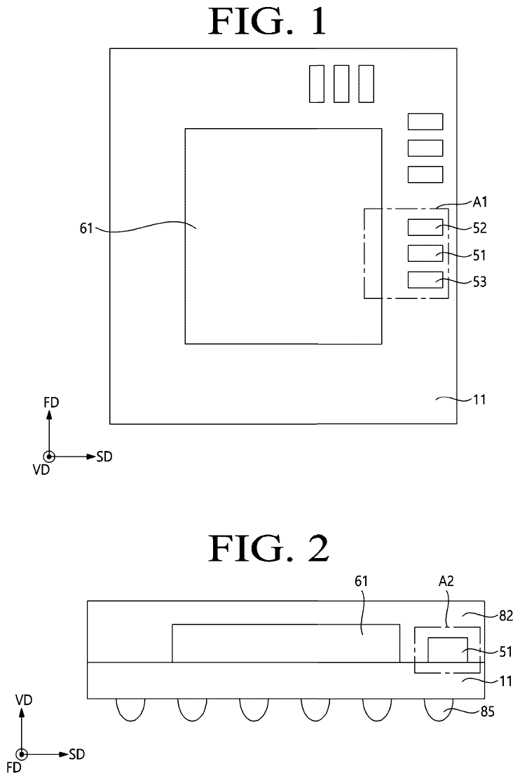

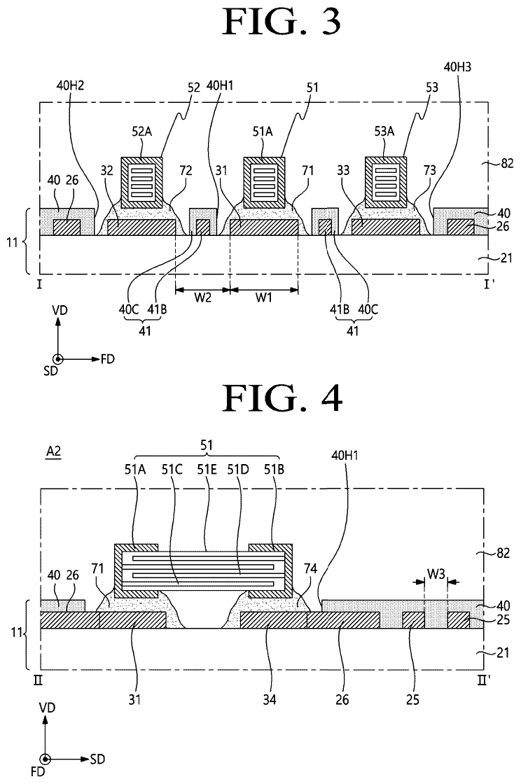

FIG. 1 is a plan view of a semiconductor package according to an embodiment of the present disclosure, and FIG. 2 is a cross-sectional view of the semiconductor package according to an embodiment of the present disclosure.

Referring to FIG. 1 and FIG. 2, the semiconductor package includes a substrate 11, passive components 51, 52, and 53, a semiconductor chip 61, an encapsulant 82, and an external terminal 85.

The passive components 51, 52, and 53 and the semiconductor chip 61 are disposed on a first surface, such as the upper surface, of the substrate 11. The encapsulant 82 covers the first surface of the substrate 11 and covers the passive components 51, 52, and 53 and the semiconductor chip 61. In an embodiment, the encapsulant 82 may include an epoxy molding compound (EMC). The external terminals 85 are attached to the second surface, such as the lower surface, of the substrate 11. The external terminals 85 include conductive bumps, solder balls, or a combination thereof.

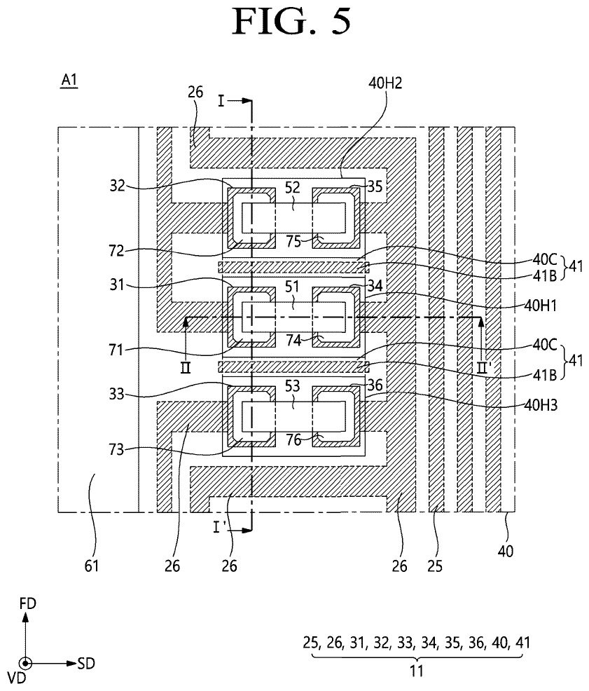

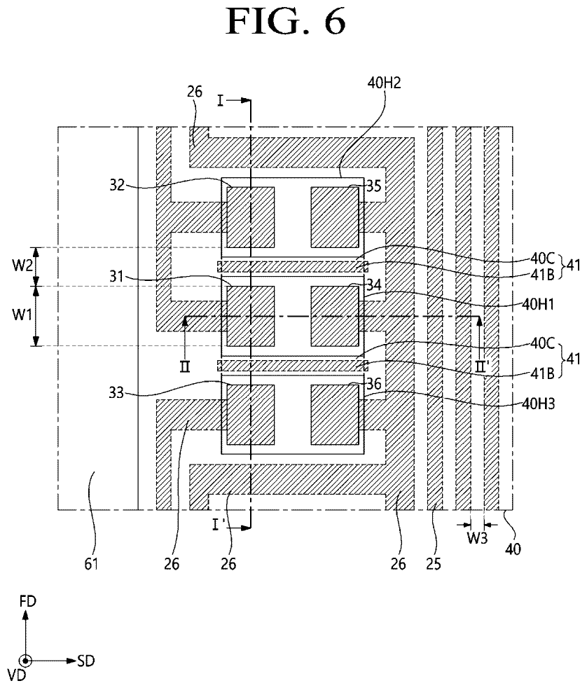

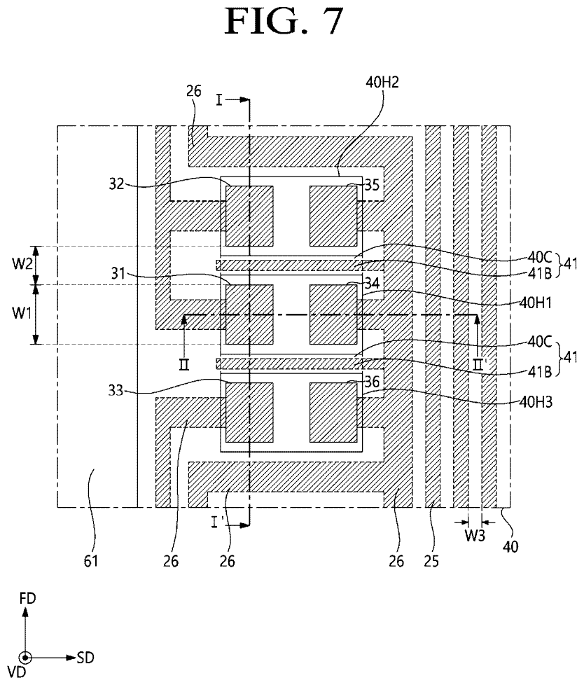

FIG. 3 and FIG. 4 are cross-sectional views of the semiconductor package according to an embodiment of the present disclosure. FIG. 4 is a partial view illustrating section A2 of FIG. 2. FIG. 5 is a plan view of the semiconductor package according to an embodiment of the present disclosure. FIG. 5 is a partial view illustrating section A1 of FIG. 1. FIG. 6 is partial view of FIG. 5. FIG. 7 is partial view of FIG. 5 according to an embodiment of the present disclosure. FIG. 3 is a cross-sectional view taken along a line I-I′ of

FIG. 5, and FIG. 4 is a cross-sectional view taken along a line II-II′ of FIG. 5.

Referring to FIG. 3, the semiconductor package includes the passive components 51, 52, and 53, solder interconnections 71, 72, and 73 and the encapsulant 82 on the substrate 11. The substrate 11 may include an insulating layer 21, a second wiring 26, electrodes 31, 32, and 33, a first solder resist layer 40, and a dam structure 41. The dam structure 41 includes a support pattern 41B and a second solder resist layer 40C. A first direction FD, a second direction SD, and a third direction VD are perpendicular to each other in the examples in the drawings. The first direction FD is parallel to the upper surface of the insulating layer 21. The second direction SD is parallel to the upper surface of the insulating layer 21 and perpendicular to the first direction FD. The third direction VD is perpendicular to the upper surface of the insulating layer 21 and perpendicular to the first direction FD and the second direction SD.

The electrodes 31, 32, and 33 may be disposed in openings 40H1, 40H2 and 40H3 formed in the first solder resist layer 40 and the second solder resist layer 40C in the third direction VD. The openings 40H1, 40H2, and 40H3 are described with reference to FIG. 6.

The electrodes 31, 32, and 33 are successively disposed in the first direction FD. A first electrode 31 has a first horizontal width

W1 in the first direction FD. A second electrode 32 and a third electrode 33 may have substantially the same horizontal width as the width of the first electrode 31. The electrodes 31, 32, and 33 are disposed spaced apart from each other. The first electrode 31 is disposed between the second electrode 32 and the third electrode 33 in the example of FIG. 3. The distance between the first electrode 31 and the second electrode 32 is second horizontal width W2. In an embodiment, the second horizontal width W2 corresponds to a minimum distance between the first electrode 31 and the second electrode 32. The minimum distance between the first electrode 31 and the third electrode 33 may be substantially the same as the minimum distance between the first electrode 31 and the second electrode 32. The second horizontal width W2 may be narrower than the first horizontal width W1. In an embodiment, the second horizontal width W2 is narrower than half of the first horizontal width W1.

The dam structures 41 are disposed adjacent to and between the openings 40H1, 40H2, and 40H3. The dam structures 41 are disposed between the electrodes 31, 32, and 33 on the insulating layer 21. In an embodiment, one support pattern 41B is disposed between the first electrode 31 and the second electrode 32, and one support pattern 41B is disposed between the first electrode 31 and the third electrode 33. The lower surface of the support pattern 41B contacts the surface of the insulating layer 21. The second solder resist layer 40C covers the support pattern 41B. The second solder resist layer 40C completely covers the upper surface and side surfaces of the support pattern 41B in the example of FIG. 3. For example, the second solder resist layer 40C covers surfaces of the support pattern 41B not adjacent to the insulating layer 21. The lower surface of the second solder resist layer 40C may directly contact the surface of the insulating layer 21. The support pattern 41B increases the thickness of the dam structure 41.

A higher bonding strength is present between the support pattern 41B and the insulating layer 21 to resist forces that may separate the support pattern and the insulating layer 21. In an embodiment, the bonding strength between the support pattern 41B and the insulating layer 21 is greater than the bonding strength between the second solder resist layer 40C and the insulating layer 21. The support pattern 41B may have high bonding strength with the second solder resist layer 40C. In an embodiment, the bonding strength between the second solder resist layer 40C and the support pattern 41B is greater than the bonding strength between the second solder resist layer 40C and the insulating layer 21. The support pattern 41B prevents the second solder resist layer 40C from being peeled off or separated from the insulating layer 21. The support pattern 41B is disposed at substantially the same level or height in the third direction VD as the electrodes 31, 32, and 33. The support pattern 41B may include the same material(s) as the electrodes 31, 32, and 33. In an embodiment, the support pattern 41B may include a copper layer formed by an electrolytic plating method.

The dam structure 41 is thicker than the electrodes 31, 32, and 33 in the third direction VD. The uppermost end or surface of the dam structure 41 is disposed at a higher level or height in the third direction VD than the level at which uppermost ends or surfaces of the electrodes 31, 32, and 33 are disposed in the third direction VD. The distance between the uppermost end of the dam structure 41 and the upper surface of the insulating layer 21 may be larger than the distance between the uppermost ends of the electrodes 31, 32, and 33 and the upper surface of the insulating layer 21. In an embodiment, the uppermost surface of the second solder resist layer 40C is disposed farther from the upper surface of the insulating layer 21 than the uppermost surfaces of the electrodes 31, 32, and 33 are disposed from the upper surface of the insulating layer 21.

The passive components 51, 52, and 53 may include capacitors, inductors, resistors, or a combination thereof. The passive components 51, 52, and 53 are disposed over the electrodes 31, 32, and 33 in the third direction VD. A first passive component 51 includes a first component electrode 51A. A first solder interconnection 71 is formed between the first electrode 31 and the first component electrode 51A. A second passive component 52 includes a second component electrode 52A. A second solder interconnection 72 is formed between the second electrode 32 and the second component electrode 52A. A third passive component 53 includes a third component electrode 53A. A third solder interconnection 73 is formed between the third electrode 33 and the third component electrode 53A. The solder interconnections 71, 72, and 73 may include tin (Sn), silver (Ag), copper (Cu), bismuth (Bi), nickel (Ni), zinc (Zn), indium (In), aluminum (Al), phosphorus (P), or a combination thereof.

A process for forming the solder interconnections 71, 72, and 73 may include a melting process such as hot air reflow, vacuum reflow, IR reflow, or laser irradiation. While the solder interconnections 71, 72, and 73 are formed, the dam structures 41 block excessive flow and spreading of solder. In an embodiment, the first solder interconnection 71 covers the first electrode 31 and extends between the first electrode 31 and the dam structures 41. The lateral end of the first solder interconnection 71 is restricted or limited to the area between the first electrode 31 and the dam structures 41. The second solder interconnection 72 covers the second electrode 32 and extends between the second electrode 32 and the dam structure 41. The lateral end of the second solder interconnection 72 is restricted or limited to the area between the second electrode 32 and the dam structures 41. The third solder interconnection 73 covers the third electrode 33 and extends between the third electrode 33 and the dam structures 41. The lateral end of the third solder interconnection 73 is restricted or limited to the area between the third electrode 33 and the dam structures 41. According to the present disclosure, the presence of the dam structures 41 reduces or prevents leakage current between the solder interconnections 71, 72, and 73 and facilitates reduction or minimization of the distance between consecutive electrodes 31, 32, and 33.

In an embodiment, the encapsulant 82 covers the insulating layer 21, the first solder resist layer 40, the dam structures 41, the passive components 51, 52, and 53, and the solder interconnections 71, 72, and 73.

Referring to FIG. 4, section A2 of the semiconductor package includes the first passive component 51, solder interconnections 71 and 74, and the encapsulant 82, and the substrate 11. The substrate 11 may include an insulating layer 21, the substrate wirings 25 and 26, the electrodes 31 and 34, and the first solder resist layer 40.

The substrate wirings 25 and 26 include a first wiring 25 and a second wiring 26. The second wiring 26 is directly connected to one of electrodes 31 and 34 in the example of FIG. 4. The first wiring 25 is spaced apart from the electrodes 31 and 34. A plurality of first wirings 25 may be disposed. The distance between consecutive first wirings 25 is a third horizontal width W3. The first solder resist layer 40 covers the insulating layer 21 and the substrate wirings 25 and 26.

A fourth electrode 34 is disposed spaced apart from the first electrode 31 in the second direction SD. The first passive component 51 is disposed over the first electrode 31 and the fourth electrode 34 in the third direction VD. In an embodiment, the first passive component 51 includes the first component electrode 51A, a fourth component electrode 51B, a first internal electrode 51C, a second internal electrode 51D, and a component insulating layer 51E.

The first solder interconnection 71 is formed between the first electrode 31 and the first component electrode 51A. A fourth solder interconnection 74 is formed between the fourth electrode 34 and the fourth component electrode 51B.

In an embodiment, the first solder resist layer 40 at least partially covers the second wiring 26. A section of the second wiring 26 near or adjacent to the first electrode 31 is disposed in a first opening 40H1 that extends through the first solder resist layer 40 in the third direction VD. The section of the second wiring 26 near or adjacent to the first electrode 31 might not be covered by the first solder resist layer 40. The first solder interconnection 71 covers the first electrode 31 and extends onto the second wiring 26. The second wiring 26 between the first solder resist layer 40 and the first solder interconnection 71 contacts the encapsulant 82 in this example. A section of the second wiring 26 near or adjacent to the fourth electrode 34 is disposed in the first opening 40H1 that passes through the first solder resist layer 40 in the third direction VD. The section of the second wiring 26 near or adjacent to the fourth electrode 34 might not be covered by the first solder resist layer 40. The fourth solder interconnection 74 covers the fourth electrode 34 and extends onto the second wiring 26. The second wiring 26 between the first solder resist layer 40 and the fourth solder interconnection 74 contacts the encapsulant 82 in this example.

In an embodiment, the first component electrode 51A and the fourth component electrode 51B are disposed at opposite ends of the first passive component 51 in the second direction SD. In an embodiment, a plurality of first internal electrodes 51C are alternately stacked with a plurality of second internal electrodes 51D in the third direction VD between the first component electrode 51A and the fourth component electrode 51B. The component insulating layer 51E is disposed between the first internal electrodes 51C and the second internal electrodes 51D. The first internal electrodes 51C are connected to the first component electrode 51A. The second internal electrodes 51D are connected to the fourth component electrode 51B.

The first component electrode 51A, the fourth component electrode 51B, the first internal electrode 51C, and the second internal electrode 51D may include a conductive material such as copper (Cu), nickel (Ni), tin (Sn), silver (Ag), gold (Au), aluminum (Al), or a combination thereof. The component insulating layer 51E may include an insulating material such as ceramic. In an embodiment, the first passive component 51 includes a multi-layer ceramic capacitor (MLCC).

In an embodiment, the encapsulant 82 covers the insulating layer 21, the first solder resist layer 40, the first passive component 51, and the solder interconnections 71 and 74.

Referring to FIG. 5, the semiconductor package includes the passive components 51, 52, and 53, the semiconductor chip 61 and solder interconnections 71, 72, 73, 74, 75, and 76, and the substrate 11. The substrate 11 may include an insulating layer 21, the substrate wirings 25 and 26, the electrodes 31, 32, 33, 34, 35, and 36, the first solder resist layer 40, and the dam structure 41.

The semiconductor chip 61 is disposed on the substrate 11. The semiconductor chip 61 includes one or more of a controller, an application processor, a microprocessor, a volatile memory, a nonvolatile memory, and so forth. In an embodiment, the passive components 51, 52, and 53 are electrically connected to the semiconductor chip 61 through the substrate wirings 25 and 26. The passive components 51, 52, and 53 may be disposed near the semiconductor chip 61. The passive components 51, 52, and 53 may be successively disposed on the substrate 11 in a line along the first direction FD. The distance between consecutive passive components 51, 52, and 53 may be small or minimized. In an embodiment, the passive components 51, 52, and 53 are disposed spaced apart from each other in the first direction FD. The passive components 51, 52, and 53 are disposed spaced apart from the semiconductor chip 61 in the second direction SD in an embodiment.

The first passive component 51 may overlap the first electrode 31 and the fourth electrode 34. The first passive component 51 is disposed at least partially over the first electrode 31 and the fourth electrode 34 in the third direction VD. The first passive component 51 is electrically connected to the semiconductor chip 61 through the first electrode 31 and/or the fourth electrode 34. The second passive component 52 may overlap the second electrode 32 and a fifth electrode 35. The second passive component 52 is disposed at least partially over the second electrode 32 and a fifth electrode 35 in the third direction VD. The second passive component 52 is electrically connected to the semiconductor chip 61 through the second electrode 32 and/or the fifth electrode 35. The third passive component 53 may overlap the third electrode 33 and a sixth electrode 36. The third passive component 53 is disposed at least partially over the third electrode 33 and a sixth electrode 36 in the third direction VD. The third passive component 53 is electrically connected to the semiconductor chip 61 through the third electrode 33 and/or the sixth electrode 36. In an embodiment, the dam structure 41 is disposed on the insulating layer 21 between the passive components 51, 52, and 53.

The substrate wirings 25 and 26 include the first wiring 25 and the second wiring 26. The second wiring 26 may be directly connected to the electrodes 31, 32, 33, 34, 35, and 36. The first wiring 25 is spaced apart from the electrodes 31, 32, 33, 34, 35, and 36. Because thermal deformation may occur while the semiconductor chip 61 within the semiconductor package operates, stress acts on the electrodes 31, 32, 33, 34, 35, and 36 connected to the passive components 51, 52, and 53. The stress may be propagated to a the second wiring 26 that contacts the electrodes 31, 32, 33, 34, 35, and 36. To make the second wiring 26 withstand the stress, the second wiring 26 may have a larger horizontal width than the first wiring 25.

As illustrated in FIG. 3 to FIG. 5, the solder interconnections 71, 72, 73, 74, 75, and 76 may be connected or bonded between the electrodes 31, 32, 33, 34, 35, and 36 and the passive components 51, 52, and 53.

The dam structure 41 includes the support pattern 41B and the second solder resist layer 40C. The first solder resist layer 40 covers the insulating layer 21 and the substrate wirings 25 and 26. As illustrated in FIG. 3 to FIG. 5, the electrodes 31, 32, 33, 34, 35, and 36 are disposed in the openings 40H1, 40H2, and 40H3 that extend through the first solder resist layer 40 and the second solder resist layer 40C in the third direction VD. The openings 40H1, 40H2, and 40H3 are described with reference to FIG. 6. The dam structures 41 are disposed between the openings 40H1, 40H2, and 40H3.

The dam structures 41 are disposed between the electrodes 31, 32, 33, 34, 35, and 36. In an embodiment, a first dam structure 41 is disposed between the first electrode 31 and the second electrode 32 and between the fourth electrode 34 and the fifth electrode 35, and a second dam structure 41 is disposed between the first electrode 31 and the third electrode 33 and between the fourth electrode 34 and the sixth electrode 36. The first dam structure 41 comprising the support pattern 41B and the second solder resist layer 40C is disposed between the first electrode 31 and the second electrode 32 and between the fourth electrode 34 and the fifth electrode 35, and the second dam structure 41 comprising the support pattern 41B and the second solder resist layer 40C is disposed between the first electrode 31 and the third electrode 33 and between the fourth electrode 34 and the sixth electrode 36.

Referring to FIG. 6, the substrate 11 includes an insulating layer 21, the substrate wirings 25 and 26, the electrodes 31, 32, 33, 34, 35 and 36, the first solder resist layer 40, and the dam structure 41. The first solder resist layer 40 covers the insulating layer 21 and the substrate wirings 25 and 26. The second solder resist layer 40C covers the support pattern 41B. As illustrated in FIG. 3 to FIG. 6, the openings 40H1, 40H2, and 40H3 that extend through the first solder resist layer 40 and the second solder resist layer 40C in the third direction VD are formed. The electrodes 31, 32, 33, 34, 35, and 36 are disposed in the openings 40H1, 40H2, and 40H3. The electrodes 31, 32, 33, 34, 35, and 36 are not covered with the first solder resist layer 40 and are not covered with the second solder resist layer 40C.

In an embodiment, the first opening 40H1 is disposed between a second opening 40H2 and a third opening 40H3. The first electrode 31 and the fourth electrode 34 are disposed in the first opening 40H1. The second electrode 32 and the fifth electrode 35 are disposed in the second opening 40H2. The third electrode 33 and the sixth electrode 36 are disposed in the third opening 40H3.

The electrodes 31, 32, and 33 are disposed spaced apart from each other in the first direction FD. The first electrode 31 is disposed between the second electrode 32 and the third electrode 33. The electrodes 31, 32, and 33 are disposed away from the semiconductor chip 61 in the second direction SD. The electrodes 34, 35, and 36 are disposed spaced apart from each other in the first direction FD. The fourth electrode 34 is disposed between the fifth electrode 35 and the sixth electrode 36. The fourth electrode 34 is disposed opposite the first electrode 31 in the second direction SD. The fifth electrode 35 is disposed opposite the second electrode 32 in the second direction SD. The sixth electrode 36 is disposed opposite the third electrode 33 in the second direction SD.

The first dam structure 41 is disposed between the first opening 40H1 and the second opening 40H2 and a second dam structure 41 is disposed between the first opening 40H1 and the third opening 40H3. The first dam structure 41, including the support pattern 41B, is disposed between the first electrode 31 and the second electrode 32 and between the fourth electrode 34 and the fifth electrode 35. The second dam structure 41, including the support pattern 41B, is disposed between the first electrode 31 and the third electrode 33 and between the fourth electrode 34 and the sixth electrode 36.

The first electrode 31 has the first horizontal width W1 in the first direction FD. Each of the second electrode 32 and the third electrode 33 have substantially the same horizontal width as the first electrode 31 in the first direction FD. The distance between the first electrode 31 and the second electrode 32 is the second horizontal width W2. In an embodiment, the second horizontal width W2 may be a minimum distance between the first electrode 31 and the second electrode 32 in the first direction FD. The minimum distance between the first electrode 31 and the third electrode 33 may be substantially the same as the second horizontal width W2. The distance between the plurality of first wirings 25 in the second direction SD is the third horizontal width W3. In an embodiment, the third horizontal width W3 may be a minimum distance between consecutive first wirings 25. The third horizontal width W3 may be determined by process capability such as the resolution limit of a patterning process. The second horizontal width W2 may be wider than the third horizontal width W3 and narrower than the first horizontal width W1. In an embodiment, the second horizontal width W2 may be narrower than half of the first horizontal width W1.

Referring to FIG. 7, in an embodiment, the support pattern 41B is connected to the second wiring 26. A first support pattern 41B extends between the first electrode 31 and the second electrode 32 and between the fourth electrode 34 and the fifth electrode 35, and a second support pattern 41B extends between the first electrode 31 and the third electrode 33 and between the fourth electrode 34 and the sixth electrode 36. In an embodiment, the support pattern 41B contacts the second wiring 26.

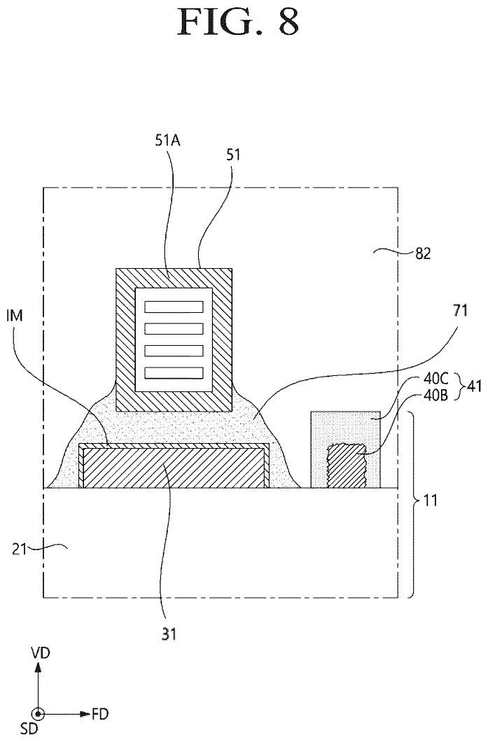

FIG. 8 is a cross-sectional view of a semiconductor package according to an embodiment of the present disclosure.

Referring to FIG. 8, an intermetallic compound layer IM is formed between the first electrode 31 and the first solder interconnection 71 in this example. The intermetallic compound layer IM is formed along the interface between the first electrode 31 and the first solder interconnection 71. The intermetallic compound layer IM contacts the upper surface and the side surfaces of the first electrode 31, but not the surface of the first electrode 31 contacting the insulating layer 21. The intermetallic compound layer IM may include a constituent material of the first electrode 31 and a constituent material of the first solder interconnection 71. Forming the intermetallic compound layer IM on the first electrode 31 may reduce the surface roughness of the first electrode 31. Similarly, an intermetallic compound layer IM may be formed between the second electrode 32 and the second solder interconnection 72, and an intermetallic compound layer IM may be formed between the third electrode 33 and the third solder interconnection 73.

The support pattern 41B contributes to the thickness of the dam structure 41 and prevents the second solder resist layer 40C from being peeled off or delaminated. The thickness of the first electrode 31 may be reduced by the intermetallic compound layer IM. The support pattern 41B may be thicker than the first electrode 31 in the third direction VD. The dam structure 41 may be thicker than the first electrode 31 in the third direction VD.

The support pattern 41B has a greater surface roughness than the first electrode 31, for example. In an embodiment, the upper surface and side surfaces of the support pattern 41B may have a greater surface roughness than the surface roughness of the upper surface and side surfaces of the first electrode 31. The upper surface and side surfaces of the support pattern 41B may have a greater surface roughness than the surface roughness of the lower surface of the support pattern 41B. In an embodiment, the upper surface and side surfaces of the support pattern 41B have a greater surface roughness than the surface roughness of the insulating layer 21. The bonding strength between the second solder resist layer 40C and the support pattern 41B may be greater than the bonding strength between the second solder resist layer 40C and the insulating layer 21. The bonding strength between the support pattern 41B and the insulating layer 21 is greater than the bonding strength between the second solder resist layer 40C and the insulating layer 21 in an embodiment.

Referring to FIG. 1 to FIG. 8, the insulating layer 21 may include a core layer, a prepreg layer, or both. The substrate wirings 25 and 26, the electrodes 31, 32, 33, 34, 35, and 36 and the support pattern 41B may be formed on, for example, the upper surface, of the insulating layer 21. The substrate wirings 25 and 26, the electrodes 31, 32, 33, 34, 35, and 36 and the support pattern 41B may include the same material(s). The substrate wirings 25 and 26, the electrodes 31, 32, 33, 34, 35, and 36 and the support pattern 41B may include metal. In an embodiment, the substrate wirings 25 and 26, the electrodes 31, 32, 33, 34, 35, and 36, and the support pattern 41B may include a copper layer.

Although the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

1. A semiconductor package comprising:
a substrate;
a semiconductor chip disposed on the substrate;
a first passive component and a second passive component disposed on the substrate; and
an encapsulant disposed on the substrate and covering the semiconductor chip, the first passive component, and the second passive component,
the substrate comprising:
an insulating layer;
a first electrode disposed on the insulating layer between the first passive component and the insulating layer in a third direction;
a second electrode disposed on the insulating layer between the second passive component and the insulating layer in the third direction and spaced apart from the first electrode in a first direction perpendicular to the third direction; and
a first dam structure disposed on the insulating layer, the first dam structure disposed between the first electrode and the second electrode and comprising:
a support pattern; and
a solder resist layer surrounding the support pattern.

2. The semiconductor package according to claim 1, wherein the support pattern includes the same material as that of the first electrode.

3. The semiconductor package according to claim 1, wherein the support pattern includes copper (Cu).

4. The semiconductor package according to claim 1, wherein the support pattern has a surface roughness greater than the surface roughness of the insulating layer.

5. The semiconductor package according to claim 1, wherein the bonding strength between the solder resist layer and the support pattern is greater than the bonding strength between the solder resist layer and the insulating layer.

6. The semiconductor package according to claim 1, wherein the bonding strength between the support pattern and the insulating layer is greater than the bonding strength between the solder resist layer and the insulating layer.

7. The semiconductor package according to claim 1, wherein the support pattern is thicker than the first electrode in the third direction.

8. The semiconductor package according to claim 1, wherein the first dam structure is thicker than the first electrode in the third direction.

9. The semiconductor package according to claim 1, further comprising:
a third electrode disposed on the insulating layer and spaced apart from the first electrode in a second direction perpendicular to the first direction; and
a fourth electrode disposed on the insulating layer and spaced apart from the second electrode in the second direction;
wherein the first passive component is disposed at least partially over the first electrode and the third electrode in the third direction,
wherein the second passive component is disposed at least partially over the second electrode and the fourth electrode in the third direction, and
wherein the first dam structure is disposed between the first electrode and the second electrode and between the third electrode and the fourth electrode.

10. The semiconductor package according to claim 9, further comprising:
a fifth electrode disposed on the insulating layer and spaced apart from the first electrode in the first direction;
a sixth electrode disposed on the insulating layer and spaced apart from the fifth electrode in the second direction; and
a third passive component disposed on the fifth electrode and the sixth electrode,
wherein the first dam structure is disposed between the first electrode and the second electrode and between the third electrode and the fourth electrode, and a second dam structure is disposed between the first electrode and the fifth electrode and between the third electrode and the sixth electrode,
wherein the first electrode is disposed between the second electrode and the fifth electrode, and
wherein the third electrode is disposed between the fourth electrode and the sixth electrode.

11. The semiconductor package according to claim 10,
wherein the first passive component, the second passive component, and the third passive component are disposed in a first direction, and
wherein the first passive component, the second passive component, and the third passive component are disposed away from the semiconductor chip in the second direction.

12. The semiconductor package according to claim 11,
wherein the first electrode, the second electrode, and the fifth electrode are disposed away from the semiconductor chip in the second direction, and
the third electrode, the fourth electrode, and the sixth electrode are disposed away from the first electrode, the second electrode, and the fifth electrode in the second direction.

13. The semiconductor package according to claim 1,
wherein the first passive component includes a first component electrode,
wherein the second passive component includes a second component electrode, and
wherein the semiconductor package further comprises:
a first solder interconnection disposed between the first electrode and the first component electrode and disposed between the first electrode and the first dam structure; and
a second solder interconnection disposed between the second electrode and the second component electrode and disposed between the second electrode and the first dam structure.

14. The semiconductor package according to claim 1, further comprising:
a plurality of substrate wirings disposed on the insulating layer,
wherein a distance between the first electrode and the second electrode is larger than a distance between consecutive substrate wirings of the plurality of substrate wirings and narrower than a width of the first electrode in the first direction.

15. The semiconductor package according to claim 1, wherein surface roughness of the support pattern is greater than surface roughness of the first electrode.

16. The semiconductor package according to claim 1, wherein the first passive component and the second passive component are disposed near the semiconductor chip.

17. A semiconductor package comprising:
an insulating layer;
a first electrode disposed on the insulating layer;
a first passive component disposed on the first electrode;
a second electrode disposed on the insulating layer and spaced apart from the first electrode in a first direction;
a second passive component disposed on the second electrode;
a first support pattern disposed between the first electrode and the second electrode and disposed on the insulating layer; and
a solder resist layer surrounding the first support pattern.

18. The semiconductor package according to claim 17, further comprising:
a third electrode disposed on the insulating layer and spaced apart from the first electrode in a second direction perpendicular to the first direction;
a fourth electrode disposed on the insulating layer and spaced apart from the second electrode in the second direction;
a fifth electrode disposed on the insulating layer and spaced apart from the first electrode in the first direction;
a sixth electrode disposed on the insulating layer and spaced apart from the fifth electrode in the second direction; and
a third passive component disposed on the fifth electrode and the sixth electrode,
wherein the first passive component is disposed on the first electrode and the third electrode,
wherein the second passive component is disposed on the second electrode and the fourth electrode,
wherein the first electrode is disposed between the second electrode and the fifth electrode,
wherein the third electrode is disposed between the fourth electrode and the sixth electrode,
wherein the first support pattern is disposed between the first electrode and the second electrode and between the third electrode and the fourth electrode, and
wherein a second support pattern is disposed between the first electrode and the fifth electrode and between the third electrode and the sixth electrode.

19. The semiconductor package according to claim 17, wherein the uppermost surface of the solder resist layer is farther away from the surface of the insulating layer than an uppermost surface of the first electrode.

20. The semiconductor package according to claim 17, wherein a surface roughness of the first support pattern is greater than a surface roughness of the first electrode.

21. A semiconductor package comprising:
a first electrode and a second electrode on an insulating layer, the first electrode and the second electrode spaced apart each other in a first direction;
a first passive component disposed on the first electrode;
a second passive component disposed on the second electrode;
a support pattern disposed on the insulating layer between the first electrode and the second electrode;
a solder resist layer surrounding the support pattern;
a first solder interconnection formed between the first electrode and the first passive component and formed between the first electrode and the solder resist layer in the first direction; and
a second solder interconnection formed between the second electrode and the second passive component and formed between the second electrode and the solder resist layer in the first direction.
